(19) United States
(12) Patent Application Publication
(10) Pub. No.: US 2010/0075453 A1
(43) Pub. Date: Mar. 25, 2010

(54) SYSTEM ARCHITECTURE AND METHOD FOR SOLAR PANEL FORMATION

(75) Inventors: Shinichi Kurita, San Jose, CA (US); Takako Takehara, Hayward, CA (US); Suhail Anwar, San Jose, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC.

(21) Appl. No.: 12/626,335

(22) Filed: Nov. 25, 2009

Related U.S. Application Data
(63) Continuation of application No. 11/733,906, filed on Apr. 11, 2007.
(60) Provisional application No. 60/791,271, filed on Apr. 11, 2006.

(51) Int. Cl. H01L 31/18

(52) U.S. Cl. 438/57; 118/715; 257/E31.001

(57) ABSTRACT

A method and apparatus for forming solar panels from n-doped silicon, p-doped silicon, intrinsic amorphous silicon, and intrinsic microcrystalline silicon using a cluster tool is disclosed. The cluster tool comprises at least one load lock chamber and at least one transfer chamber. When multiple clusters are used, at least one buffer chamber may be present between the clusters. A plurality of processing chambers are attached to the transfer chamber. As few as five and as many as thirteen processing chambers can be present.

### CROSS-REFERENCE TO RELATED APPLICATIONS

This application is a continuation application of co-pending U.S. patent application Ser. No. 11/733,906 (attorney docket No. 10901), filed on Apr. 11, 2007, which claims benefit of U.S. Provisional Patent Application Ser. No. 60/791,271 (APPM/010901L), filed Apr. 11, 2006, which is herein incorporated by reference.

### BACKGROUND OF THE INVENTION

1. Field of the Invention

Embodiments of the present invention generally relate to substrate processing apparatuses and methods such as apparatuses and methods for flat panel display processing (i.e. LCD, OLED, and other types of flat panel displays), semiconductor wafer processing, and solar panel processing.

2. Description of the Related Art

In depositing on large area substrates (i.e., flat panel displays, solar cells, etc.), substrate throughput can be a challenge. Therefore, there is a need for an improved apparatus and method.

### SUMMARY OF THE INVENTION

The present invention generally comprises a method and an apparatus for forming solar panels from n-doped silicon, p-doped silicon, intrinsic amorphous silicon, and intrinsic microcrystalline silicon using a cluster tool. The cluster tool comprises at least one load lock chamber and at least one transfer chamber. When multiple clusters are used, at least one buffer chamber may be present between the clusters. A plurality of processing chambers are attached to the transfer chamber.

In one embodiment, a cluster tool arrangement is disclosed. The cluster tool arrangement comprises a plurality of six-sided transfer chambers, one or more buffer chambers coupled between adjacent six-sided transfer chambers, one or more p-doped silicon deposition chambers coupled to one of the six-sided transfer chambers, one or more n-doped silicon deposition chambers coupled to one of the six-sided transfer chambers, and a plurality of intrinsic silicon deposition chambers coupled to the plurality of six-sided transfer chambers. The number of intrinsic silicon deposition chambers is greater than the number of p-doped silicon deposition chambers and the number of n-doped silicon deposition chambers combined.

In another embodiment, a PIN structure formation method is disclosed. The method comprises (a) disposing a first substrate in a p-doped silicon deposition chamber and depositing a p-doped silicon layer on the first substrate, (b) transferring the first substrate to a first intrinsic silicon deposition chamber and depositing an intrinsic silicon layer on the p-doped silicon layer on the first substrate, (c) disposing a second substrate in the p-doped silicon deposition chamber and depositing a p-doped silicon layer on the second substrate, (d) transferring the second substrate to a second intrinsic silicon deposition chamber and depositing an intrinsic silicon layer on the p-doped silicon layer on the second substrate, the depositing an intrinsic silicon layer on the p-doped silicon layer on the second substrate occurring simultaneously with the deposition of the intrinsic silicon layer on the p-doped silicon layer on the first substrate, (e) disposing a third substrate in the p-doped silicon deposition chamber and depositing a p-doped silicon layer on the third substrate, (f) transferring the third substrate to a third intrinsic silicon deposition chamber and depositing an intrinsic silicon layer on the p-doped silicon layer on the third substrate, the depositing an intrinsic silicon layer on the p-doped silicon layer on the third substrate occurring simultaneously with the depositing the intrinsic silicon layer on the p-doped silicon layer on the second substrate, (g) disposing a fourth substrate in the p-doped silicon deposition chamber and depositing a p-doped silicon layer on the fourth substrate, (h) transferring the first substrate to an n-doped silicon deposition chamber and depositing an n-doped silicon layer on the intrinsic silicon layer on the first substrate, and (i) transferring the fourth substrate to the first intrinsic silicon deposition chamber and depositing an intrinsic silicon layer on the p-doped silicon layer on the fourth substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a single cluster tool of the present invention.

FIG. 2 is a double cluster tool of the present invention.

FIGS. 3-5 are triple cluster tools of the present invention.

FIGS. 6A-6C are cluster tools of the present invention.

### DETAILED DESCRIPTION

The present invention describes a method and apparatus for forming solar panels using a cluster tool. The cluster tool comprises at least one load lock chamber and at least one transfer chamber. When multiple clusters are used, at least one buffer chamber may be present between the clusters. A plurality of processing chambers are attached to the transfer chamber. As few as five and as many as thirteen processing chambers can be present within the cluster tool. The solar panel may be formed from n-doped silicon, p-doped silicon, intrinsic amorphous silicon, and intrinsic microcrystalline silicon.

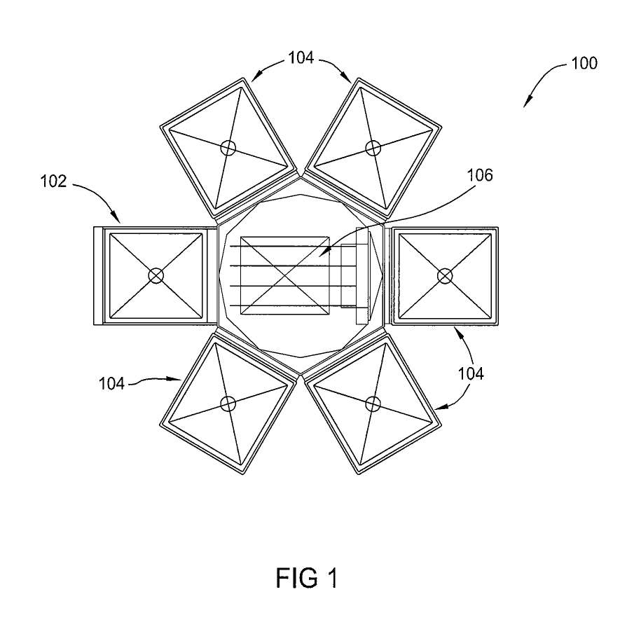

FIG. 1 shows a single cluster tool 100 that can be used to form an amorphous silicon single PIN junction solar panel. The chamber has a single load lock chamber 102 and a single transfer chamber 106. Surrounding the transfer chamber are five processing chambers 104. In one embodiment of the cluster tool configured to make a single PIN junction, each process chamber 104 can deposit each layer (i.e., p-doped silicon, intrinsic silicon, and n-doped silicon). In another embodiment, the cluster tool configured to make a single PIN junction, one process chamber 104 can deposit the p-doped silicon layer, three process chambers 104 can deposit the intrinsic silicon layer, and one process chamber 104 can deposit the n-doped silicon layer. The single cluster tool can process about 18 substrates per hour when forming an amorphous silicon single PIN junction solar panel.

In another embodiment, the single cluster tool 100 can be configured to make crystalline silicon on glass. One process chamber 104 can be configured to deposit the n-doped silicon layer and one process chambers 104 can be configured to deposit the p-doped silicon layer. Three process chambers 104 can be used to deposit the SiNₓ layer.

In another embodiment, the single cluster tool 100 can be configured to form a double PIN junction cell. In one embodiment of the cluster tool 100 configured to make the double PIN junction cell, each process chamber 104 can deposit each layer (i.e., p-doped silicon layer, intrinsic amorphous silicon layer, and n-doped silicon layer). In another embodiment of the cluster tool configured to make the double PIN junction cell, one process chamber 104 can deposit the p-doped silicon layer, one process chamber 104 can deposit the n-doped silicon layer, and three process chambers 104 can deposit the intrinsic amorphous silicon layer.

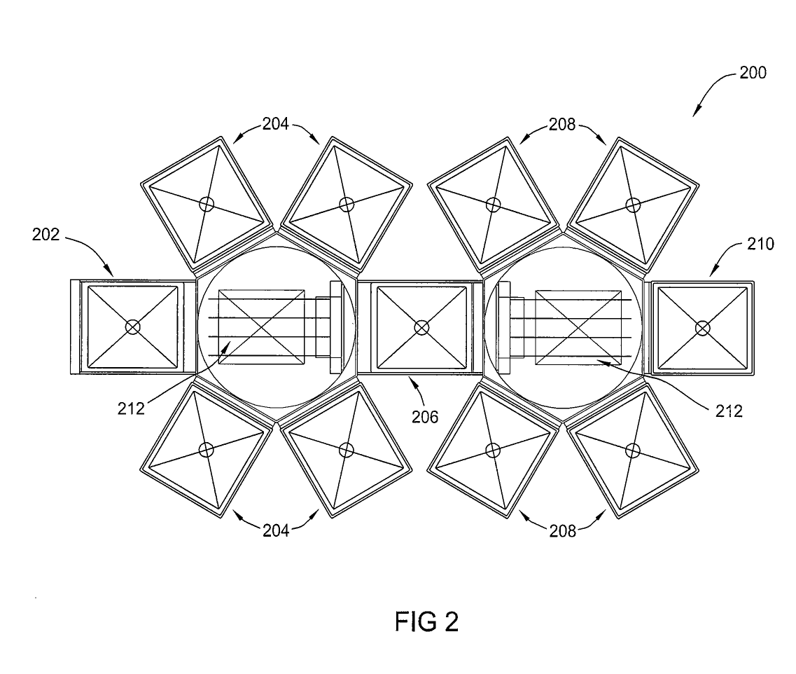

FIG. 2 shows a double cluster tool 200 that can be used to form an amorphous silicon PINPIN double junction. The cluster tool has two transfer chambers 212, a buffer chamber 206 between the transfer chambers 212, a load lock chamber 202, and an unload lock chamber 210, although it is possible to remove the unload lock chamber 210 and replace it with an additional processing chamber. The additional processing chamber that would be used is likely to be an intrinsic amorphous silicon deposition chamber. Generally, the processing chamber that would replace the load lock chamber would be a processing chamber performing the process in the sequence that takes the most time. Processing chambers 204 surround one of the transfer chambers 212 and additional process chambers 208 surround the other transfer chamber 212. By adding an additional chamber to deposit the slowest depositing layer, substrate backlog may be reduced.

The cluster tool 200 of FIG. 2 can be used to form a hybrid micromorph cell or amorphous silicon/microcrystalline silicon tandem cell. In one embodiment of the cluster tool 200 configured to make the hybrid or tandem cell, each process chamber 204, 208 can deposit each layer (i.e., p-doped silicon layer, intrinsic amorphous silicon layer, intrinsic microcrystalline silicon layer, and n-doped silicon layer). In another embodiment of the cluster tool 200 configured to make the hybrid or tandem cell, one process chamber 204 can deposit the p-doped silicon layer, one process chamber 204 can deposit the n-doped silicon layer, two process chambers 204 can deposit the intrinsic amorphous silicon layer, and four or five process chambers 208 can deposit the intrinsic microcrystalline silicon layer.

For one embodiment of an amorphous silicon PINPIN double junction, the double cluster tool may have three p-doped silicon deposition chambers, two n-doped silicon deposition chambers, and three or four intrinsic amorphous silicon deposition chambers. In another embodiment, one p-doped silicon deposition chamber, one n-doped silicon deposition chamber, and six or seven intrinsic amorphous silicon deposition chambers are present. The throughput for the amorphous silicon PINPIN double junction using a double cluster tool is about 18 substrates per hour.

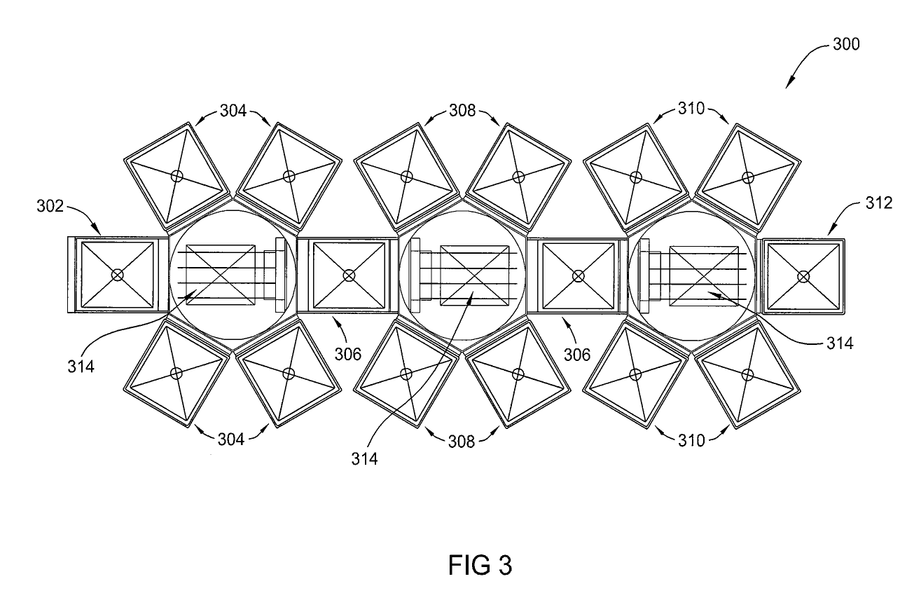

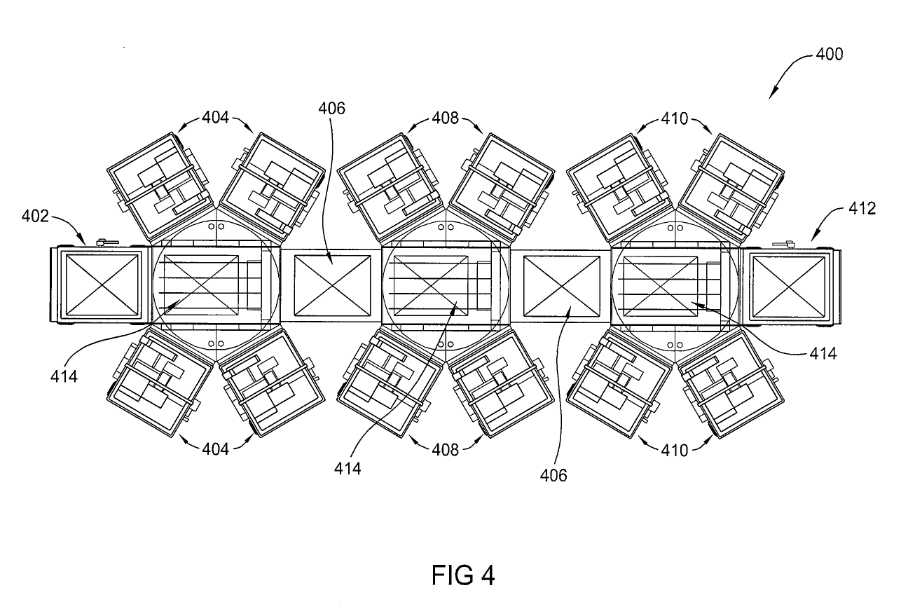

FIG. 3 shows a linear triple cluster tool 300 that can be used to deposit an amorphous silicon/microcrystalline silicon tandem PINPIN double junction. By linear cluster tool 300, it is understood to mean that the load lock 302, transfer chamber 314, unload lock 312, and any buffer chambers 306 are along the same linear plane. The cluster tool 300 has an unload lock chamber 312, although it is possible to remove the unload lock chamber 312 and replace it with an additional processing chamber. The additional processing chamber that would be used is likely to be an intrinsic microcrystalline silicon deposition chamber. Generally, the processing chamber that would replace the load lock chamber would be a processing chamber performing the process in the sequence that takes the most time. The intrinsic microcrystalline silicon layer is usually the slowest layer to form. Therefore, if the unload lock chamber 312 is to be replaced by a processing chamber, the processing chamber may generally be an intrinsic microcrystalline silicon deposition chamber. By adding an additional chamber to deposit the slowest depositing layer, substrate backlog may be reduced. The cluster tool, when in a straight line form that is shown in FIGS. 3 and 4, may be about 22000 mm long and about 11000 mm wide for a substrate that is 1950 mm×2250 mm, in one embodiment (See FIG. 4).

Three transfer chambers 314 are present that are surrounded by processing chambers 304, 308, 310. Two buffer chambers 306 are also present between the clusters. A buffer chamber 306 is between the first and second clusters, and a buffer chamber 306 is present between the second and third cluster.

The cluster tool 300 of FIG. 3 can be used to form a hybrid micromorph cell or amorphous silicon/microcrystalline silicon tandem cell. In one embodiment of the cluster tool 300 configured to make the hybrid or tandem cell, each process chamber 304, 308, 310 can deposit each layer (i.e., p-doped silicon layer, intrinsic amorphous silicon layer, intrinsic microcrystalline silicon layer, and n-doped silicon layer). In another embodiment of the cluster tool 300 configured to make the hybrid or tandem cell, one process chamber 304 can deposit the p-doped silicon layer, one process chamber 304 can deposit the n-doped silicon layer, two process chambers 304 can deposit the intrinsic amorphous silicon layer, and eight or nine process chambers 308, 310 can deposit the intrinsic microcrystalline silicon layer.

The cluster tool 300 of FIG. 3 can be used to form a double PIN junction cell. In one embodiment of the cluster tool 300 configured to make the double PIN junction cell, each process chamber 304, 308, 310 can deposit each layer (i.e., p-doped silicon layer, intrinsic amorphous silicon layer, and n-doped silicon layer). In another embodiment of the cluster tool 300 configured to make the double PIN junction cell, one process chamber 304 can deposit the p-doped silicon layer, one process chamber 304 can deposit the n-doped silicon layer, and ten or eleven process chambers 304, 308, 310 can deposit the intrinsic amorphous silicon layer.

FIG. 4 shows a triple cluster tool 400 that has a load lock chamber 402, process chambers 404, 408, 410, buffer chambers 406, transfer chambers 414, and an unload lock chamber 412.

The cluster tool 400 of FIG. 4 can be used to form a hybrid micromorph cell or amorphous silicon/microcrystalline silicon tandem cell. In one embodiment of the cluster tool 400 configured to make the hybrid or tandem cell, each process chamber 404, 408, 410 can deposit each layer (i.e., p-doped silicon layer, intrinsic amorphous silicon layer, intrinsic microcrystalline silicon layer, and n-doped silicon layer). In another embodiment of the cluster tool 400 configured to make the hybrid or tandem cell, one process chamber 404 can deposit the p-doped silicon layer, one process chamber 404 can deposit the n-doped silicon layer, two process chambers 404 can deposit the intrinsic amorphous silicon layer, and eight or nine process chambers 408, 410 can deposit the intrinsic microcrystalline silicon layer.

The cluster tool 400 of FIG. 4 can be used to form a double PIN junction cell. In one embodiment of the cluster tool 400 configured to make the double PIN junction cell, each process chamber 404, 408, 410 can deposit each layer (i.e., p-doped silicon layer, intrinsic amorphous silicon layer, and n-doped silicon layer). In another embodiment of the cluster tool configured to make the double PIN junction cell, one process chamber 404 can deposit the p-doped silicon layer, one process chamber 404 can deposit the n-doped silicon layer, and ten or eleven process chambers 404, 408, 410 can deposit the intrinsic amorphous silicon layer.

The triple cluster tool can process about 14 substrates an hour in forming the amorphous silicon/microcrystalline silicon tandem double junction solar panel. Between each p-doped silicon layer deposition and each intrinsic silicon layer deposition, the chambers are purged for about 300 seconds.

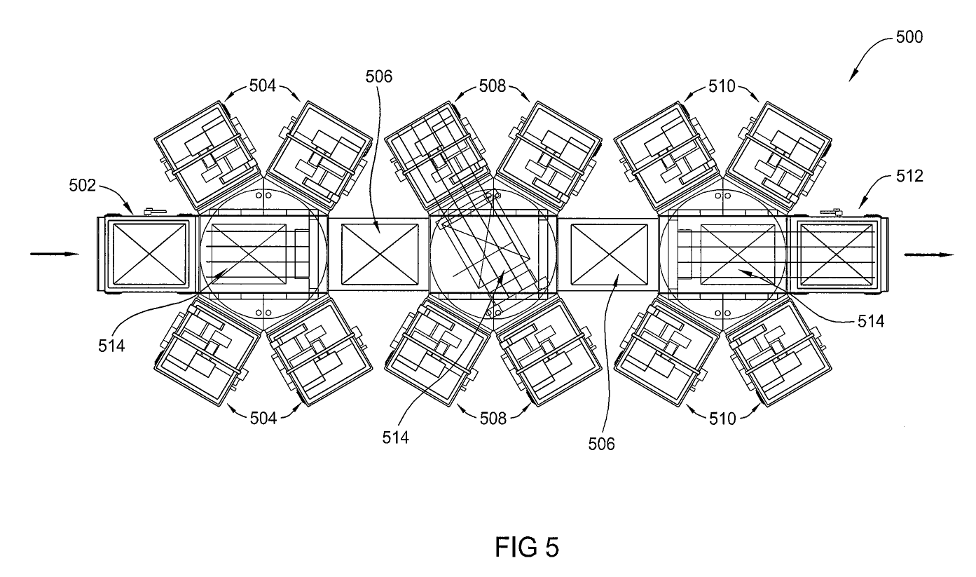

FIG. 5 shows a linear triple cluster tool 500 that has a load lock chamber 502 and an unload lock chamber 512. The load lock chamber 502 and unload lock chamber 512 are single slot chambers. A single slot chamber is a chamber that has only one slot that opens to the processing cluster environment. The processing cluster environment is comprised of all areas contained within the processing chambers 504, 508, 510, transfer chambers 514, load lock chambers 502, 512, and buffer chambers 506.

The buffer chambers 506 are dual slot chambers. Each slot opens to a transfer chamber 514. The transfer robot that is contained within the transfer chamber 514 is a dual arm vacuum robot or a single arm vacuum robot. The transfer chamber 514 is under vacuum; therefore the robot is a vacuum robot. The robot has two arms that are used to grasp and support the substrate as it is moved from chamber to chamber.

Within the transfer chambers 514, the robot may rotate about the center of the chamber. The robot arms can extend into the adjacent chambers to place and remove a substrate. Each of the chambers has a slot that faces the transfer chamber 514. When the deposition is CVD, the transfer chamber 514 may operate at a base pressure of about 1 Torr. When the processing chamber is a PVD chamber, the transfer chamber 514 may operate at a base pressure of about 1 mTorr. The buffer chamber 506 can have a slit valve for isolation to prevent contamination between CVD and PVD processing chambers that surround the cluster transfer chamber 514. In such a situation, one of the clusters would have PVD deposition and another would have CVD deposition. If only CVD or only PVD will be performed within the cluster tool, then no slit valve need be present in the buffer chamber 506. The buffer chamber 506 can provide active heating or cooling to the substrate. The buffer chamber 506 can also align the substrate to compensate for substrate position error that can occur during substrate transferring. The robot may have the ability to rotate about the transfer chamber 514 and extend into the buffer 506 and processing chambers 504, 508, 510. The robot can also move in the z-direction.

The cluster tool 500 of FIG. 5 can be used to form a hybrid micromorph cell or amorphous silicon/microcrystalline silicon tandem cell. In one embodiment of the cluster tool 500 configured to make the hybrid or tandem cell, each process chamber 504, 508, 510 can deposit each layer (i.e., p-doped silicon layer, intrinsic amorphous silicon layer, intrinsic microcrystalline silicon layer, and n-doped silicon layer). In another embodiment of the cluster tool 500 configured to make the hybrid or tandem cell, one process chamber 504 can deposit the p-doped silicon layer, one process chamber 504 can deposit the n-doped silicon layer, two process chambers 504 can deposit the intrinsic amorphous silicon layer, and eight or nine process chambers 508, 510 can deposit the intrinsic microcrystalline silicon layer.

The cluster tool 500 of FIG. 5 can be used to form a double PIN junction cell. In one embodiment of the cluster tool 500 configured to make the double PIN junction cell, each process chamber 504, 508, 510 can deposit each layer (i.e., p-doped silicon layer, intrinsic amorphous silicon layer, and n-doped silicon layer). In another embodiment of the cluster tool 500 configured to make the double PIN junction cell, one process chamber 504 can deposit the p-doped silicon layer, one process chamber 504 can deposit the n-doped silicon layer, and ten or eleven process chambers 504, 508, 510 can deposit the intrinsic microcrystalline silicon layer.

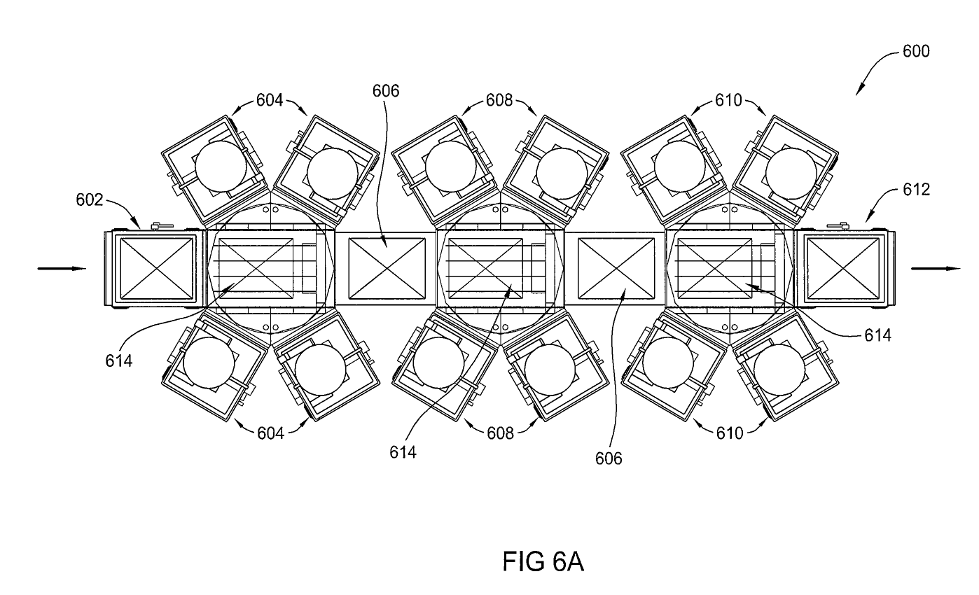

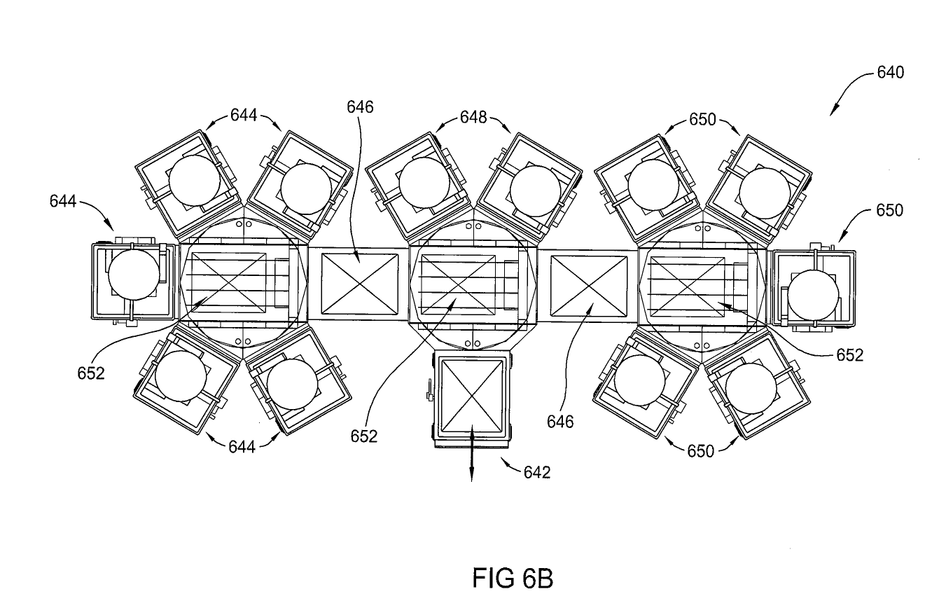

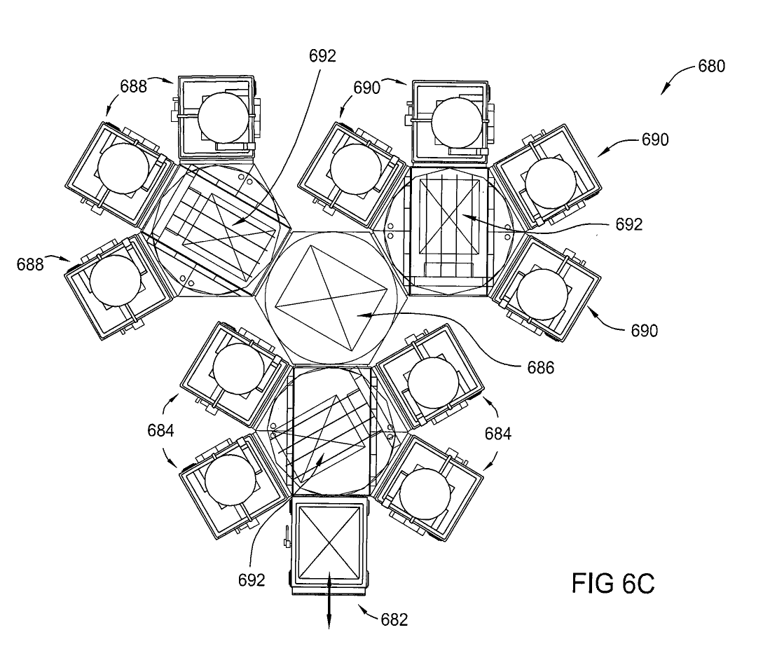

FIG. 6A shows another linear triple cluster tool 600 of the present invention. The cluster tool 600 has a load lock chamber 602, an unload lock chamber 612, process chambers 604, 608, 610, three transfer chambers 614, and two buffer chambers 606.

FIG. 6B shows a center fed triple cluster tool 640. Only one load lock 642 and twelve processing chambers 644, 648, 650 are present. The load lock 642 is present at the center cluster. The left cluster contains five processing chambers 644 and the right cluster also contains five processing chambers 650. Three transfer chambers 652 and two buffer chambers 642 are also present.

FIG. 6C shows a single buffer chamber 686 triple cluster tool 680. One load lock 682, twelve processing chambers 684, 688, 690, and three transfer chambers 692 are present. Only one buffer chamber 686 is present. The three clusters are centered around the buffer chamber so that the buffer chamber has three slots, one for each transfer chamber.

The cluster tools 600, 640, 680 of FIG. 6A-6C can be used to form a hybrid micromorph cell or amorphous silicon/microcrystalline silicon tandem cell. In one embodiment of the cluster tools 600, 640, 680 configured to make the hybrid or tandem cell, each process chamber 604, 608, 610, 644, 648, 650, 684, 688, 690 can deposit each layer (i.e., p-doped silicon layer, intrinsic amorphous silicon layer, intrinsic microcrystalline silicon layer, and n-doped silicon layer). In another embodiment of the cluster tool 600, 640, 680 configured to make the hybrid or tandem cell, one process chamber 604, 644, 684 can deposit the p-doped silicon layer, one process chamber 604, 644, 684 can deposit the n-doped silicon layer, two process chambers 604, 644, 684 can deposit the intrinsic amorphous silicon layer, and eight or nine process chambers 608, 610, 648, 650, 688, 690 can deposit the intrinsic microcrystalline silicon layer.

The cluster tools 600, 640, 680 of FIG. 6A-6C can be used to form a double PIN junction cell. In one embodiment of the cluster tools 600, 640, 680 configured to make the double PIN junction cell, each process chamber 604, 608, 610, 644, 648, 650, 684, 688, 690 can deposit each layer (i.e., p-doped silicon layer, intrinsic amorphous silicon layer, and n-doped silicon layer). In another embodiment of the cluster tools 600, 640, 680 configured to make the double PIN junction cell, one process chamber 604, 644, 684 can deposit the p-doped silicon layer, one process chamber 604, 644, 684 can deposit the n-doped silicon layer, and eight or nine process chambers 604, 608, 610, 644, 648, 650, 684, 688, 690 can deposit the intrinsic amorphous silicon layer.

The cluster tool is very beneficial to use when forming solar panels. The cluster tool provides a flexible configuration that is configurable for the various processing chamber combinations necessary to form PIN junctions. The cluster tool also provides a high throughput so that the process chamber utilization can be optimized. There is a high mechanical reliability, a high particle performance, and high mean time between failure (MTBF). The material cost and cost of operation (COO) are also low. There is a low process risk when using the cluster tool configurations.

The solar panel substrates can be of varying size. For example, the substrate can be 1950×2250 mm². The throughput for the cluster tool systems is about 20 substrates processed per hour. The cluster tool systems can have about 5 to about 13 processing chambers per system.

When forming a single PIN junction, a single cluster tool can be used. The single cluster tool may have a single load lock chamber and five processing chambers. Because the intrinsic silicon may deposit about 3 times slower than the n-doped silicon layer and about three times slower than the p-doped silicon layer, three processing chambers for depositing the intrinsic silicon layer are present and only one n-doped silicon deposition chamber and one p-doped silicon deposition chamber are present. The single cluster tool may process about 10.4 to about 17.6 substrates per hour. In contrast, when a single chamber is used to deposit all layers of the PIN junction, the throughput is only about 9.9 to about 14.1 substrates per hour.

When forming an amorphous silicon/microcrystalline silicon tandem double junction, a double cluster or triple cluster tool can be used. When using a double cluster tool, the p-doped silicon layer and the n-doped silicon layer may deposit in about half the time of the intrinsic amorphous silicon layer. The p-doped silicon layer and the n-doped silicon layer may deposit about eight times faster than the intrinsic microcrystalline layer. Therefore, because two p-doped silicon layers are present in the structure and two n-doped silicon layers are present in the structure, two separate depositions for each layer may occur. Therefore, a single p-doped silicon deposition chamber, a single n-doped silicon deposition chamber, a single intrinsic amorphous silicon deposition chamber can be present, and four intrinsic microcrystalline silicon deposition chamber can be present. In one embodiment, two intrinsic amorphous silicon processing chambers are present. The throughput for the double cluster tool may be about 9.4 substrates per hour.

When using the triple cluster tool, the number of intrinsic amorphous silicon deposition chambers and the number of intrinsic microcrystalline silicon deposition chambers increases while the number of n-doped silicon and p-doped silicon deposition chambers stays the same. The throughput for the triple cluster tool is about 9.4 substrates per hour, just as the double cluster tool. In contrast, if a single chamber is used to deposit the entire structure, about 2.2 to about 6.3 substrates per hour can be processed.

When forming an intrinsic amorphous silicon PINPIN double junction structure, a single cluster tool can be used. The intrinsic amorphous silicon for the first PIN junction may take about twice as long to deposit as the n-doped silicon and the p-doped silicon layers. For the second PIN junction, the intrinsic amorphous silicon may take anywhere from twice as long to four times as long to deposit as compared to the p-doped silicon layer and the n-doped silicon layer. Therefore, a single p-doped silicon deposition chamber and a single n-doped silicon deposition chamber are needed. Two to three intrinsic amorphous silicon deposition chambers may be needed to form the intrinsic amorphous silicon for both PIN junctions of the structure. The throughput for the single cluster tool may be about 8.3 to about 14.5 substrates per hour. In contrast, when a single chamber is used to deposit all of the layers, about 5.9 to about 14.5 substrates per hour can be processed.

The intrinsic amorphous silicon and the intrinsic microcrystalline silicon layers take longer to deposit than the n-doped silicon layers and the p-doped silicon layers because the intrinsic silicon layers are deposited to a greater thickness than the doped silicon layers. The amorphous silicon may be deposited at about 50 nm per minute and the microcrystalline silicon can be deposited at about 100 nm per minute.

When forming an amorphous silicon/microcrystalline silicon PINPIN tandem double junction, a processing sequence can be followed. A double or triple cluster system may be used. A first substrate may enter through the load lock chamber and pass into the p-doped silicon deposition chamber. The first substrate may then have a p-doped silicon layer deposited thereon. Following deposition of the p-doped silicon layer, the first substrate may be transferred to a first intrinsic amorphous silicon deposition chamber.

While the first substrate is within the intrinsic amorphous silicon deposition chamber, a second substrate is placed into the p-doped silicon deposition chamber. Following the deposition of the p-doped silicon layer on the second substrate, the second substrate is transferred to a second amorphous silicon deposition chamber.

While the intrinsic amorphous silicon layer is being deposited on the first substrate and the second substrate (in separate intrinsic amorphous silicon deposition chambers), a third substrate is placed in the p-doped silicon deposition chamber for processing. A p-doped silicon layer is deposited on the third substrate while an intrinsic amorphous silicon layer is deposited on the first and second substrates.

Following the deposition of the intrinsic amorphous silicon layer on the first substrate, the first substrate is moved to the n-doped silicon deposition chamber and the third substrate is moved into the first intrinsic amorphous silicon deposition chamber. Following the deposition of the n-doped silicon layer on the first substrate, the first substrate is transferred to the p-doped silicon deposition chamber, and the second substrate is transferred to the n-doped silicon deposition chamber.

Following the deposition of the second p-doped silicon layer on the first substrate, the first substrate is transferred into the second cluster through the buffer chamber and then placed into an intrinsic microcrystalline silicon deposition chamber. Following the n-doped silicon deposition on the second substrate, the second substrate is transferred into the p-doped silicon deposition chamber. The third substrate is transferred from the first intrinsic amorphous silicon deposition chamber to the n-doped silicon deposition chamber.

Following the deposition of the p-doped silicon layer on the second substrate, the second substrate is transferred to the second cluster system to be placed in an intrinsic microcrystalline deposition chamber. Following the deposition of the deposition of the n-doped silicon layer on the third substrate, the third substrate is transferred to the p-doped silicon deposition chamber.

Once the p-doped silicon layer is deposited on the third substrate, the third substrate is transferred to the second cluster and placed into an intrinsic microcrystalline silicon deposition chamber. Once the intrinsic microcrystalline silicon layer is deposited onto the first substrate, the first substrate is transferred back to the first cluster and placed in the n-doped silicon deposition chamber. Once the n-doped silicon layer is deposited on the first substrate, the first substrate is transferred to the load lock chamber and out of the system. Once the intrinsic microcrystalline silicon layer is deposited onto the second substrate, the second substrate is transferred back to the first cluster and placed in the n-doped silicon deposition chamber. Once the n-doped silicon layer is deposited on the second substrate, the second substrate is transferred to the load lock chamber and out of the system.

Once the intrinsic microcrystalline silicon layer is deposited onto the third substrate, the third substrate is transferred back to the first cluster and placed in the n-doped silicon deposition chamber. Once the n-doped silicon layer is deposited on the third substrate, the third substrate is transferred to the load lock chamber and out of the system.

While the process sequence described above has been described with respect to only three substrates, it is to be understood that additional substrate could be processed simultaneously. So long as the substrates may be processed within the processing chambers and transferred between the processing chambers without the need to transfer more substrates than the robot can handle or process more substrates than can be processed at one time, the number of substrates to be processed may be based upon the time that a substrate may be processed within a given chamber and the number of chambers available for processing at any moment in time.

For the intrinsic microcrystalline silicon deposition, because the intrinsic microcrystalline silicon layer is thicker than either the n-doped silicon, the p-doped silicon, or the intrinsic amorphous silicon, the substrate may need to remain in the intrinsic microcrystalline silicon processing chamber longer than within the other processing chambers. For that reason, it is beneficial to have more intrinsic microcrystalline silicon deposition chambers than the other processing chambers. By having more intrinsic microcrystalline silicon deposition chambers, the additional substrates can be processed in the ‘quicker’ deposition chambers and placed in the additional microcrystalline silicon deposition chambers. Ideally, the number of intrinsic microcrystalline silicon deposition chambers may be chosen so that as soon as one of the intrinsic microcrystalline silicon deposition chambers finishes processing, the substrate is removed and a new substrate is placed within the processing chamber.

The same reasoning applies for the intrinsic amorphous silicon deposition chambers. Ideally, the number of intrinsic amorphous silicon deposition chambers may be chosen so that as soon as one of the intrinsic amorphous silicon deposition chambers finishes processing, the substrate is removed and a new substrate is placed within the processing chamber. In fact, the quickness with which the intrinsic amorphous silicon and intrinsic microcrystalline silicon chambers can deposit material helps determine not only the number of chambers necessary, but also whether a single, double, or triple cluster system is necessary. Naturally, the decision as to whether a single junction or double junction structure is to be formed may also determine whether a single or double or triple cluster tool may be needed.

A p-doped silicon deposition chamber may have about a 270 second preheating prior to each deposition. Each of the other deposition chambers may have about a 50 second preheat prior to each deposition. The p-doped silicon layer may be deposited to a thickness of about 20 nm. The intrinsic amorphous silicon layer may be deposited to about 150 nm to about 300 nm thickness. The n-doped silicon layer can be deposited to a thickness of about 20 nm. The intrinsic microcrystalline silicon layer may be about 300 nm thick.

While the foregoing is directed to embodiments of the present invention, other and further embodiments of the invention may be devised without departing from the basic scope thereof, and the scope thereof is determined by the claims that follow.

What is claimed is:

1. A cluster tool arrangement, comprising:
at least one transfer chamber;
at least one load lock chamber coupled to the at least one transfer chamber;
at least six intrinsic silicon deposition chambers coupled to the at least one transfer chamber, wherein each of the at least six intrinsic silicon deposition chambers are configured to deposit both an intrinsic silicon layer and an n-doped silicon layer; and
a substrate transfer robot disposed in the at least one transfer chamber.

2. The cluster tool arrangement of claim 1, further comprising at least one p-doped silicon deposition chamber coupled to the at least one transfer chamber.

3. The cluster tool arrangement of claim 2, wherein the number of intrinsic silicon deposition chambers is greater than the number of p-doped silicon deposition chamber.

4. The cluster tool arrangement of claim 2, wherein the at least one p-doped silicon deposition chamber is coupled to the same transfer chamber with at least a portion of the at least six intrinsic silicon deposition chambers.

5. The cluster tool arrangement of claim 4, wherein the at least one transfer chamber comprises three transfer chambers coupled together in a non-linear arrangement.

6. The cluster tool arrangement of claim 1, wherein a first portion of the at least six intrinsic silicon deposition chamber is configured to deposit an intrinsic amorphous silicon layer and a second portion of the at least six intrinsic silicon deposition chambers is configured to deposit an intrinsic crystalline silicon layer.

7. The cluster tool arrangement of claim 1, further comprising a plurality of physical vapor deposition chambers, wherein the plurality of physical vapor deposition chambers and the at least six intrinsic silicon deposition chambers are connected to different transfer chambers.

8. The cluster tool arrangement of claim 1, wherein the substrate transfer robot comprises two arms each configured to grasp and support a large area substrate in a horizontal orientation.

9. A cluster tool arrangement, comprising:
one or two load lock chambers coupled to a processing cluster environment;
one p-doped silicon deposition chamber coupled to the processing cluster environment;
six or seven intrinsic silicon deposition chambers coupled to the processing cluster environment, wherein the six or seven intrinsic silicon deposition chambers are configured to deposit both an intrinsic silicon layer and an n-doped silicon layer; and
a vacuum robot disposed in the processing cluster environment.

10. The cluster tool arrangement of claim 9, wherein the processing cluster environment comprises one or more transfer chambers.

11. The cluster tool arrangement of claim 10, wherein the p-doped silicon deposition chamber is coupled to the same transfer chamber with at least a portion of the six or seven intrinsic silicon deposition chambers.

12. The cluster tool arrangement of claim 9, wherein a first portion of the six or seven intrinsic silicon deposition chamber is configured to deposit an intrinsic amorphous silicon layer and a second portion of the six or seven intrinsic silicon deposition chambers is configured to deposit an intrinsic crystalline silicon layer.

13. The cluster tool arrangement of claim 9, wherein the vacuum robot comprises two arms each configured to grasp and support a large area substrate in a horizontal orientation.

14. A method for forming a PIN structure, comprising:
transferring a substrate to a cluster tool comprising:
at least one transfer chamber;
at least one load lock chamber coupled to the at least one transfer chamber;
at least six intrinsic silicon deposition chambers coupled to the at least one transfer chamber; and
a substrate transfer robot disposed in the at least one transfer chamber; and
depositing a first intrinsic silicon layer and a first n-doped silicon layer on the p-doped silicon layer on the substrate in one of the at least six intrinsic silicon deposition chambers.

15. The method of claim 14, further comprising, prior to the depositing the first intrinsic silicon layer and the first n-doped silicon layer, depositing a first p-doped silicon layer on the substrate in a p-doped silicon deposition chamber coupled to the at least one transfer chamber.

16. The method of claim 15, wherein the first intrinsic silicon layer is intrinsic microcrystalline silicon layer.

17. The method of claim 15, wherein the first intrinsic silicon layer is intrinsic amorphous silicon layer.

18. The method of claim 17, further comprising:
depositing a second p-doped silicon layer; and
depositing a second intrinsic silicon layer and a second n-doped silicon layer.

19. The method of claim 14, wherein the second intrinsic silicon layer is microcrystalline silicon layer, and depositing the second p-doped silicon layer, the second intrinsic layer and second n-doped silicon layer are performed in processing chambers coupled to a transfer chamber other than the at least one transfer chamber.

20. The method of claim 14, further comprising transferring the substrate within the cluster tool using a vacuum robot comprises two arms each configured to grasp and support the substrate in a horizontal orientation.
